(19) United States
(12) Patent Application Publication
(10) Pub. No.: US 2009/0258134 A1
(43) Pub. Date: Oct. 15, 2009

(54) METHOD FOR CONTROLLING THIN-FILM FORMING VELOCITY, METHOD FOR MANUFACTURING THIN-FILM USING THE SAME AND SYSTEM FOR MANUFACTURING A THIN-FILM USING THE SAME

(75) Inventors: Joo-Hyeon LEE, Yongin-si (KR); Chang-Woong CHU, Suwon-si (KR); Won-Hoe KOO, Suwon-si (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 12/369,196

(22) Filed: Feb. 11, 2009

(30) Foreign Application Priority Data
Apr. 15, 2008 (KR) 2008-34795

(51) Int. Cl. C23C 16/52

(52) U.S. Cl. 427/8; 118/715; 118/708

(57) ABSTRACT

In a method for controlling thin-film forming velocity, a method for manufacturing a thin film and a system for manufacturing the thin film, the method for controlling the thin-film forming velocity includes measuring the thin-film forming velocity at a target substrate by sensing a depositing source gas generated from a depositing source part. Then, a distance between the depositing source part and the target substrate is controlled so that the thin-film forming velocity substantially equals a predetermined thin-film forming velocity. Accordingly, the thin-film forming velocity is controlled by changing the distance between the depositing source part and the target substrate, so that time spent in controlling the thin-film forming velocity may be decreased.

This application claims priority to Korean Patent Application No. 2008-34795, filed on Apr. 15, 2008, and all the benefits accruing therefrom under 35 U.S.C. §119, the contents of which in its entirety are herein incorporated by reference.

### BACKGROUND OF THE INVENTION

1. Field of the Invention

The present invention relates to a method for controlling thin-film forming velocity, a method for manufacturing a thin film using the method for controlling the thin-film forming velocity and a system for manufacturing the thin film using the method for controlling the thin-film forming velocity. More particularly, the present invention relates to a method for controlling thin-film forming velocity to manufacture an organic light-emitting diode (“OLED”), a method for manufacturing a thin film using the method for controlling the thin-film forming velocity and a system for manufacturing the thin film using the method for controlling the thin-film forming velocity.

2. Description of the Related Art

Generally, materials forming an organic light-emitting diode (“OLED”) are formed on a target substrate by a thin-film forming apparatus. The materials may include an organic material, an inorganic material, a metal material and various other similar materials.

The thin-film forming apparatus typically includes a vacuum depositing chamber disposed on the target substrate and a vacuum source part generating gases of the materials. The depositing source part includes an inner container receiving the materials and a container heater disposed outside of the inner container. The container heater heats the inner container to increase a temperature thereof, and thus the quantity of the gas of the materials generated from the depositing source part may be increased.

When the quantity of the gas of the materials is increased, quantity of the materials deposited on the target substrate is also increased, so that a thin-film forming velocity may be increased. Thus, the container heater may control the thin-film forming velocity on the target substrate via controlling the temperature of the inner container.

However, the temperature of the inner container is not easily changed because of characteristics of the materials which form the inner container, which may be made of materials such as ceramic. Accordingly, the thin-film forming velocity on the target substrate may not be readily controlled, because the temperature of the inner container is not readily controlled by the container heater.

When the thin-film forming velocity on the target substrate is not rapidly controlled by the container heater, it takes more time for the thin-film forming velocity to reach a predetermined target velocity. When the thin-film forming velocity is controlled by the container heater, it may take more time to control the thin-forming velocity.

### BRIEF SUMMARY OF THE INVENTION

The present invention provides a method for controlling a thin-film forming velocity to decrease control time spent for the thin-film forming velocity to reach a target velocity.

The present invention also provides a method for manufacturing a thin film using the method for controlling the thin-film forming velocity.

The present invention also provides a system for manufacturing the thin film to perform the method for controlling the thin-film forming velocity.

In an exemplary method for controlling a thin-film forming velocity according to the present invention, the method includes; measuring the thin-film forming velocity on a target substrate by sensing a depositing source gas generated from a depositing source part, and controlling a distance between the depositing source part and the target substrate, so that the thin-film forming velocity substantially equals a predetermined thin-film forming velocity.

Exemplary embodiments of the method may further include controlling a quantity of the depositing source gas generated from the depositing source part.

In one exemplary embodiment, the quantity of the depositing source gas may be controlled by controlling a temperature of the depositing source part. In one exemplary embodiment, the quantity of the depositing source gas may be controlled by sensing a temperature of the depositing source part, and by controlling the temperature of the depositing source part to substantially equal a predetermined temperature.

In one exemplary embodiment, the distance between the depositing source part and the target substrate may be controlled by controlling the distance after the temperature of the depositing source part substantially equals the predetermined temperature. In one exemplary embodiment, the distance between the depositing source part and the target substrate may be controlled within a predetermined distance range.

In an exemplary method for manufacturing a thin film according to the present invention, the method includes; measuring a thin-film forming velocity on a target substrate by sensing a depositing source gas generated from a depositing source part, controlling a distance between the depositing source part and the target substrate, so that the thin-film forming velocity substantially equals a predetermined thin-film forming velocity, and depositing a depositing source on the target substrate with the predetermined thin-film forming velocity.

In one exemplary embodiment, the method may further include controlling a quantity of the depositing source gas generated from the depositing source part.

In one exemplary embodiment, the quantity of the depositing source gas may be controlled by controlling a temperature of the depositing source part.

In one exemplary embodiment, the depositing source may be deposited on the target substrate by opening a depositing shutter when the thin-film forming velocity substantially equals the predetermined thin-film forming velocity.

In an exemplary embodiment of a system for manufacturing the thin film according to the present invention, the system includes a depositing chamber in which a target substrate is disposed, a depositing source part, which generates a depositing source gas, disposed in the depositing chamber, a thin-film forming velocity sensor, which measures a thin-film forming velocity on the target substrate by sensing the depositing source gas, and a distance control part which controls a distance between the depositing source part and the target substrate so that the thin-film forming velocity substantially equals a predetermined thin-film forming velocity.

In one exemplary embodiment, the TS distance control part may include a thin-film forming velocity controller which outputs a thin-film forming velocity control signal in response to the thin-film forming velocity measured by the thin-film forming velocity sensor, a position controller which outputs a position variable control signal to control the distance between the deposition source part and the target substrate in response to the thin-film forming velocity control signal and a position variable unit which changes the distance between the depositing source part and the target substrate by moving the depositing source part in response to the position variable control signal.

In one exemplary embodiment, the system may further include a gas generating control part which controls a quantity of the depositing source gas generated from the depositing source part.

In one exemplary embodiment, the gas generating control part may include a temperature control part which controls a temperature of the depositing source part.

In one exemplary embodiment, the temperature control part may include; a temperature sensor attached to the depositing source part, a temperature controller which outputs a temperature control signal in response to a temperature sensing signal sent from the temperature sensor, and a temperature variable unit which changes the temperature in response to the temperature control signal.

In one exemplary embodiment, the depositing source part may include an inner container which receives the depositing source, and a container heater which surrounds the inner container and which is controlled by the temperature variable unit, wherein the temperature sensor is attached to the inner container and the temperature sensing signal corresponds to a temperature of the inner container.

In one exemplary embodiment, the depositing source part may further include an external container which receives the container heater and the inner container and which insulates the container heater from an outside.

In one exemplary embodiment, the system may further include a main controller, which individually controls the distance control part and the gas generating control part, and is electrically connected to the TS distance control part and the gas generating control part respectively.

In one exemplary embodiment, the system may further include a depositing shutter disposed corresponding to the target substrate in the depositing chamber.

In one exemplary embodiment, the TS distance control part may store information on a relationship between the distance between the depositing source part and the target substrate and the thin-film forming velocity.

According to the present invention, the distance between the depositing source part and the target substrate is changed to control the thin-film forming velocity depositing a depositing source on the target substrate, so that it may take less time for the thin-film forming velocity to reach the predetermined target velocity.

### BRIEF DESCRIPTION OF THE DRAWINGS

The above and other features and advantages of the present invention will become more apparent by describing in detailed example embodiments thereof with reference to the accompanying drawings, in which:

FIG. 1 is a schematic plan view illustrating an exemplary embodiment of a system for manufacturing a thin film according to the present invention;

FIG. 2 is a graph showing a relation between a thin-film forming velocity and a TS distance D between a depositing source part and a target substrate of FIG. 1;

FIG. 3 is a schematic plan view illustrating an exemplary embodiment of a system for manufacturing the thin film further including a gas generating control part;

FIG. 4 is a cross-sectional view illustrating the depositing source part of FIG. 3;

FIG. 5 is a schematic plan view illustrating an exemplary embodiment of a system for manufacturing the thin film further including a main controller; and

FIG. 6 is a graph illustrating an exemplary embodiment of a process for forming the thin film on the target substrate using the system of FIG. 5.

### DETAILED DESCRIPTION OF THE INVENTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and areas may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, areas, layers and/or sections, these elements, components, areas, layers and/or sections should not be limited by these terms. These terms are only used to distinguish one element, component, area, layer or section from another area, layer or section. Thus, a first element, component, area, layer or section discussed below could be termed a second element, component, area, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of areas illustrated herein but are to include deviations in shapes that result, for example, from manufacturing. For example, an implanted area illustrated as a rectangle will, typically, have rounded or curved features and/or a gradient of implant concentration at its edges rather than a binary change from implanted to non-implanted area. Likewise, a buried area formed by implantation may result in some implantation in the area between the buried area and the surface through which the implantation takes place. Thus, the areas illustrated in the figures are schematic in nature and their shapes are not intended to illustrate the actual shape of an area of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be explained in detail with reference to the accompanying drawings.

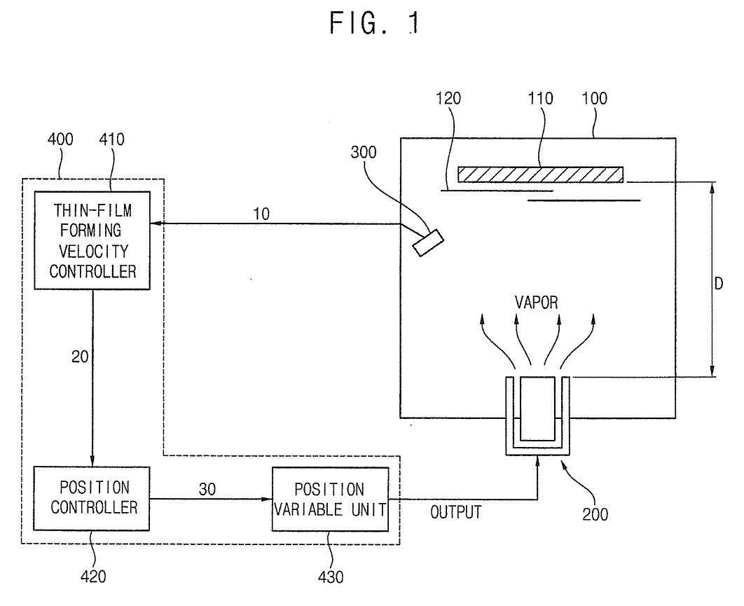

FIG. 1 is a schematic plan view illustrating an exemplary embodiment of a system for manufacturing a thin film according to the present invention.

Referring to FIG. 1, the exemplary embodiment of a system for manufacturing the thin film according to the present invention includes a depositing chamber 100, a depositing source part 200, a thin-film forming velocity sensor 300 and a TS distance control part 400.

The depositing chamber 100 includes an inner space to receive a target substrate 110. The target substrate 110 is disposed in the depositing chamber 100. In one exemplary embodiment, the target substrate 110 may be disposed at an upper portion of the inner space. In one exemplary embodiment, the inner space of the depositing chamber 100 may be maintained to be in a vacuum state.

A depositing shutter 120 may be disposed adjacent to the target substrate 110 in the depositing chamber 100. In one exemplary embodiment, the depositing shutter 120 may be disposed under the target substrate 110 to face the target substrate 110. The depositing shutter 120 determines a beginning of depositing the thin film on the target substrate I 10, e.g., when the depositing shutter 120 is open, the thin film starts to be deposited on the target substrate 110. However, when the depositing shutter 120 is closed, the deposition of the thin film on the target substrate 110 ends.

The depositing source part 200 is disposed in the depositing chamber 100 to generate a depositing source gas. In one exemplary embodiment, the depositing source part 200 may be disposed at a lower portion of the inner space facing the target substrate 110. Hereinafter, a distance between the depositing source part 200 and the target substrate 110 is referred to as the target-to-source (“TS”) distance D.

When the depositing shutter 120 is open, the depositing source gas generated from the depositing source part 200 is deposited on the target substrate 110 to form a thin film. In this case, when the quantity of the depositing source gas is increased, a rate of depositing the depositing source gas on the target substrate 110 may be increased. Hereinafter, the rate of depositing the depositing source gas on the target substrate 110 is referred to as the thin-film forming velocity.

The thin-film forming velocity sensor 300 is disposed in the depositing chamber 100, to sense the depositing source gas generated from the depositing source part 200. In one exemplary embodiment, the thin-film forming velocity sensor 300 may be disposed at the upper portion of the inner space.

The thin-film forming velocity sensor 300 senses the depositing source gas to indirectly measure the thin-film forming velocity on the target substrate 110, and to output a thin-film forming velocity sensing signal 10 including an information on the thin-film forming velocity. The thin-film forming velocity sensor 200 is disposed adjacent to the target substrate 110, so that the thin-film forming velocity sensor 200 may accurately measure the thin-film forming velocity. In one exemplary embodiment, the thin-film forming velocity sensing signal 10 may be a crystal sensor that measures the thin-film forming velocity via a change in frequency.

The TS distance control part 400 controls a position of the depositing source part 200 in response to the thin-film forming velocity sensing signal 10 generated from the thin-film forming velocity sensor 300. In one exemplary embodiment, the TS distance control part 400 controls the TS distance D in response to the thin-film forming velocity sensing signal 10, so that the thin-film forming velocity on the target substrate 110 may be changed.

In one exemplary embodiment, the TS distance control part 400 may include a thin-film forming velocity controller 410, a position controller 420 and a position variable unit 430.

The thin-film forming velocity controller 410 receives the thin-film forming velocity sensing signal 10 from the thin-film forming velocity sensor 300, and outputs a thin-film forming velocity control signal 20 in response to the information on the thin-film forming velocity included in the thin-film forming velocity sensing signal 10.

The position controller 420 receives the thin-film forming velocity control signal 20 from the thin-film forming velocity controller 410, and outputs a position variable control signal 30 to control the TS distance D in response to the thin-film forming velocity control signal 20.

The position variable unit 430 receives the position variable control signal 30 from the position controller 420, and changes a position of the depositing source part 200 in response to the position variable control signal 30. In one exemplary embodiment, the position variable unit 430 may control the TS distance D in response to the position variable control signal 30. In one exemplary embodiment, the position variable unit 430 may include a motor (not shown) or a cylinder (not shown) moving the depositing source part 200.

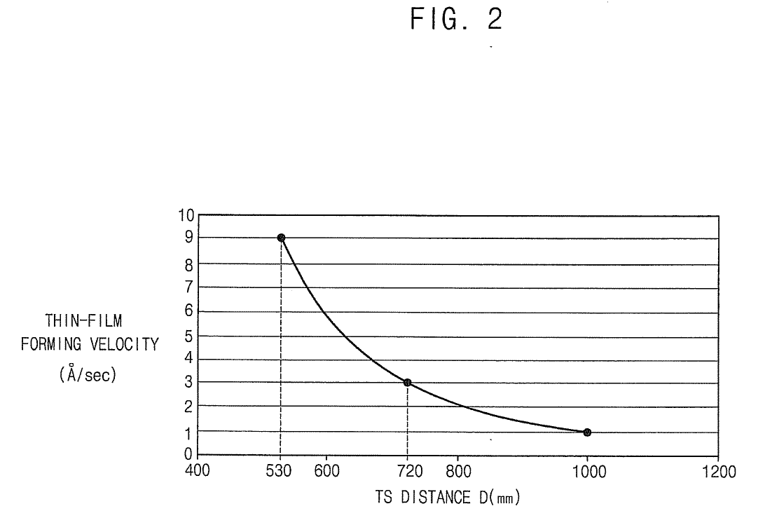

FIG. 2 is a graph showing a relation between a thin-film forming velocity and a TS distance D between a depositing source part and a target substrate of FIG. 1.

Referring to FIGS. 1 and 2, the TS distance D is inversely proportional to the thin-film forming velocity. In one exemplary embodiment, as the TS distance D is decreased, the thin-film forming velocity is increased.

In one exemplary embodiment, when the TS distance D is about 1,000 mm, the thin-film forming velocity may be about 1 Å/sec, when the TS distance D is about 720 mm, the thin-film forming velocity may be about 3 Å/sec, and when the TS distance D is about 530 mm, the thin-film forming velocity may be about 9 Å/sec.

Accordingly, the TS distance D is decreased to increase the thin-film forming velocity, and the TS distance D is increase to decrease the thin-film forming velocity. Thus, the thin-film forming velocity may be controlled by controlling the TS distance D.

In one exemplary embodiment, the relation between the TS distance D and the thin-film forming velocity may be changed according to an inner size of the depositing chamber 100, a vacuum state in the depositing chamber, a type of the depositing, characteristics of the depositing source part and various other characteristics of the depositing chamber 100 and the deposition process.

The information on the relation between the TS distance D and the thin-film forming to velocity may be stored in the TS distance control part 400. In one exemplary embodiment, the thin-film forming velocity controller 410 may store the information on the relation between the TS distance D and the thin-film forming velocity. Alternatively, the information on the relation between the TS distance D and the thin-film forming velocity may be stored to an additional external memory (not shown). In one exemplary embodiment, the external memory may provide the information on the TS distance D and the thin-film forming velocity to the TS distance control part 400.

The TS distance control part 400 may control the TS distance D, using the information on the relation between the TS distance D and the thin-film forming velocity and the information on a predetermined thin-film forming velocity. In one exemplary embodiment, the TS distance control part 400 may store the information on the predetermined thin-film forming velocity or may receive the information from outside.

In one exemplary embodiment, when the TS distance control part 400 determines that the thin-film forming velocity measured by the thin-film forming velocity sensor 300 is not substantially the same as the predetermined thin-film forming velocity, the TS distance control part 400 changes the TS distance D so that the thin-film forming velocity substantially reaches the predetermined thin-film forming velocity. Thus, the TS distance control part 400 may control the TS distance D so that the thin-film forming velocity may be substantially the same as the predetermined thin-film forming velocity.

Accordingly, the TS distance D is controlled using the information on the relation between the TS distance D and the thin-film forming velocity, so that the thin-film forming velocity may be controlled quickly and accurately.

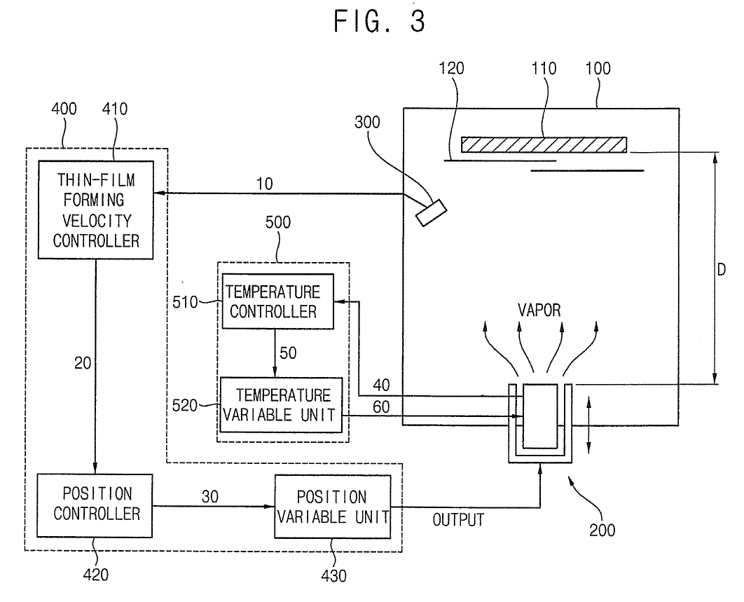

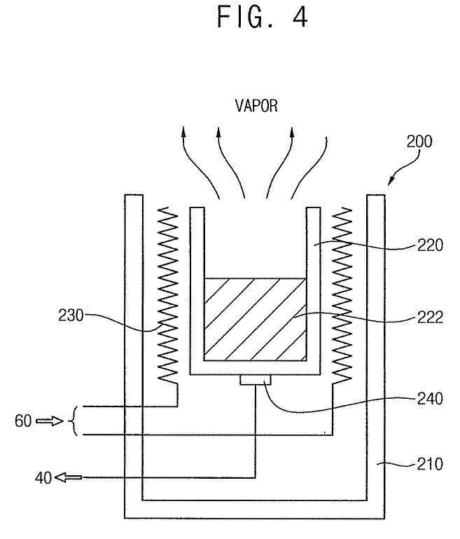

FIG. 3 is a schematic plan view illustrating an exemplary embodiment of a system for manufacturing the thin film further including a gas generating control part. FIG. 4 is a cross-sectional view illustrating the depositing source part of FIG. 3.

Referring to FIGS. 3 and 4, an exemplary embodiment of the thin-film forming system may further include a gas generating control part 500 controlling a quantity of the depositing source gas.

The gas generating control part 500 may be electrically connected to the depositing source part 200 to control the quantity of the depositing source gas generated from the depositing source part 200. In such an exemplary embodiment, when the quantity of the depositing source gas is increased, the thin-film forming velocity on the target substrate 110 is also increased.

In one exemplary embodiment, the gas generating control part 500 may include a temperature control part. The temperature control part controls a temperature of the depositing source part 200 to control the quantity of the depositing source gas generated from the depositing source part 200. In one exemplary embodiment, the temperature control part may include a temperature controller 510 and a temperature variable unit 520.

The temperature controller 510 receives a temperature sensing signal 40 having the information on the temperature from the depositing source part 200. The temperature controller 510 outputs a temperature control signal 50 to control the temperature in response to the temperature sensing signal 40.

The temperature variable unit 520 receives the temperature control signal 50 from the temperature controller 510, and outputs a temperature output signal 60 to the depositing source part 200 in response to the temperature control signal 50. The temperature of the depositing source part 200 may be changed in response to the temperature output signal 60. In one exemplary embodiment, the temperature variable unit 520 may include a silicon controlled rectifier (“SCR”).

In one exemplary embodiment, the depositing source part 200 may include an external container 210 and a depositing source unit received by the external container 210. The depositing source unit may be controlled by the temperature control part to generate the depositing source gas. In one exemplary embodiment, the depositing source unit may include an inner container 220, a container heater 230 and a temperature sensor 240.

The external container 210 receives the depositing source unit to insulate the depositing source unit from an outside. The inner container 220 is received by the external container 210, and a depositing source 222 is disposed in the inner container 220.

The container heater 230 is disposed outside of the inner container 220 to provide the heat to the inner container 220. In one exemplary embodiment, the container heater 230 may change the temperature of the inner container 220. In such an exemplary embodiment, when the temperature is increased, the depositing source 222 disposed in the inner container 220 is evaporated to generate the depositing source gas. The container heater 230 is received by the external container 210, to be insulated from the outside.

The container heater 230 may receive the temperature output signal 60 from the temperature variable unit 520, and may control the temperature of the inner container 220 in response to the temperature output signal 60.

The temperature sensor 240 is disposed adjacent to the inner container 220 to sense the temperature of the inner container 220, and outputs the temperature sensing signal 40 having information on the temperature thereof to the temperature controller 510. In one exemplary embodiment, the temperature sensor 240 may include a thermocouple.

The temperature sensor 240 may be attached to an outer surface or an inner surface of the inner container 220, to sense the temperature of the inner container 220 more accurately. In one exemplary embodiment, the temperature sensor 240 may be attached to a bottom surface of the inner container 220.

The temperature control part may control the temperature of the inner container 220 using a predetermined temperature. Exemplary embodiments include configurations wherein the predetermined temperature may be stored in the temperature control part or applied from outside. When the temperature control part determines that the temperature measured by the temperature sensor 240 is not substantially the same as the predetermined temperature, the temperature control part may change the temperature to substantially equal the predetermined temperature. In one exemplary embodiment, the temperature control part may control the container heater 230 so that the temperature of the inner container 220 may substantially reach the predetermined temperature.

Accordingly, the gas generating control part 500 controls the depositing source gas generated from the depositing source part, and the TS distance control part 400 controls the TS distance, so that the thin-film forming velocity may be controlled more easily and more accurately.

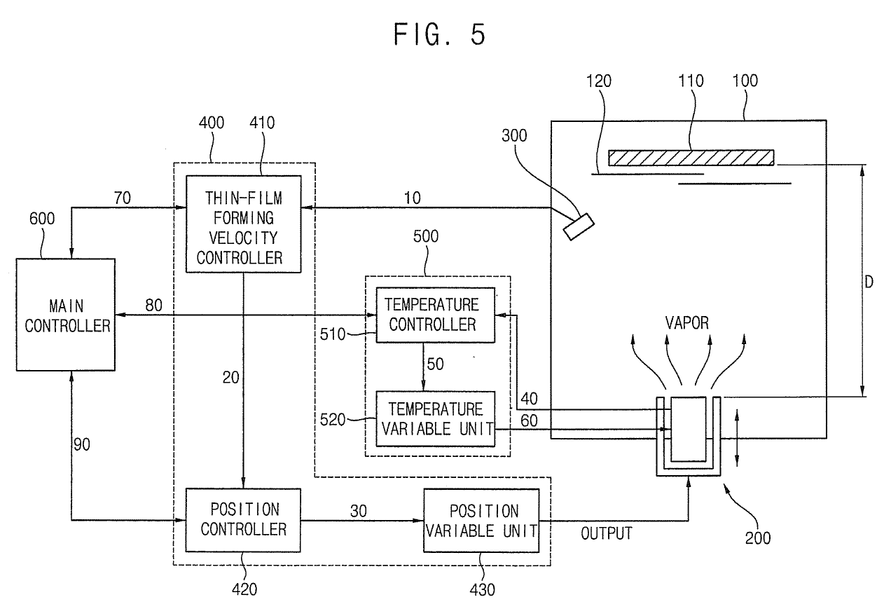

FIG. 5 is a schematic plan view illustrating a system for manufacturing the thin-film further including a main controller.

Referring to FIG. 5, the system for manufacturing the thin film may further include a main controller 600 controlling the TS distance control part 400 and the gas generating control part 500 respectively. The main controller 600 may transmit signals to the TS distance control part 400 and the gas generating control part 500, and may receive the signals from the TS distance control part 400 and the gas generating control part 500, through an RS-232 process.

In the present exemplary embodiment, the main controller 600 transmits a first control signal 70 to the thin-film forming velocity controller 410 and receives the first control signal 70 from the thin-film forming velocity controller 410, to control the thin-film forming velocity controller 410 directly. In addition, the main controller 600 transmits a second control signal 80 to the temperature controller 510 and receives the second control signal 80 from the temperature controller 510, to control the temperature controller 510 directly. In addition, the main controller 600 transmits a third control signal 90 to the position controller 420 and receives the third control signal 90 from the position controller 420, to control the position controller 420 directly.

The main controller 600 may provide the information on the relation between the TS distance and the thin-film forming velocity, the predetermined thin-film forming velocity and the predetermined temperature, to the TS distance control part 400, the gas generating control part 500, or both.

An exemplary embodiment of a method for controlling the thin-film forming velocity and an exemplary embodiment of a method for manufacturing the thin film having the method for controlling the thin-film forming velocity according to the present invention will be explained as follows.

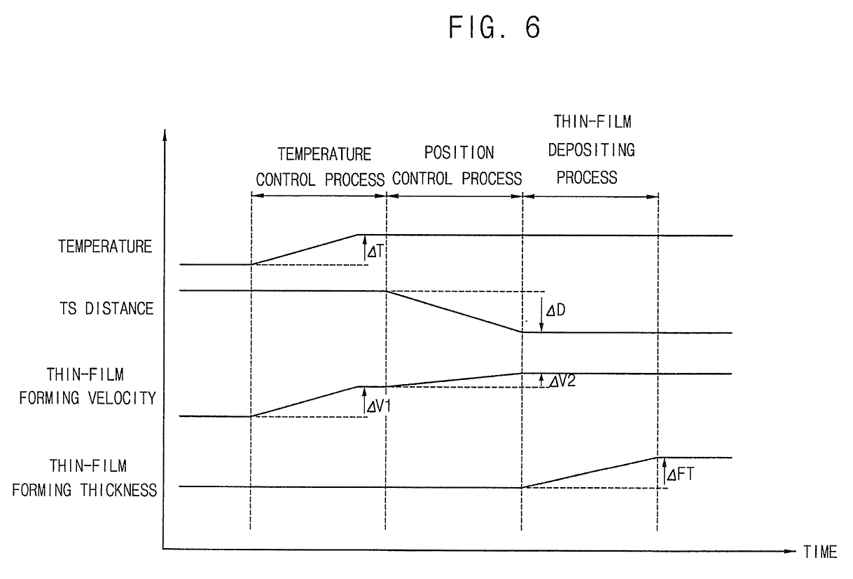

FIG. 6 is graph illustrating exemplary embodiments of processes for forming the thin film on the target substrate using the exemplary embodiment of a system of FIG. 5.

Referring to FIGS. 5 and 6, the current exemplary embodiment of a method for manufacturing the thin film according to the present invention may include a process for controlling a temperature, a process for controlling a position and a process for depositing a thin film.

First, the temperature is controlled. In one exemplary embodiment, the process for controlling the temperature may include a process for controlling the temperature of the depositing source part 200 to control the quantity of the depositing source gas generated from IS the depositing source part 200. The process for controlling the temperature may include a process for sensing the temperature of the depositing source part 200 and a process for controlling the temperature of the depositing source part 200. In one exemplary embodiment, in the process for controlling the temperature, the temperature of the depositing source part 200 is sensed, and then, when the temperature of the depositing source part 200 is not substantially the same as the predetermined temperature, the temperature of the depositing source part 200 is changed to be substantially equal to the predetermined temperature.

In one exemplary embodiment, the temperature of the depositing source part 200 is increased by an increased temperature ΔT. When the temperature of the depositing source part 200 is increased by the increased temperature ΔT, the thin-film forming velocity on the target substrate 110 may be increased by a first increased thin-film forming velocity ΔV1 corresponding to the increased temperature ΔT.

After the temperature is controlled, the position is controlled. In one exemplary embodiment, the process for controlling the temperature may include a process for controlling a position of the depositing source part 200 to control the thin-film forming velocity on the target substrate 110. In the process for controlling the position, the TS distance D is controlled to control the thin-film forming velocity on the target substrate 110.

The process for controlling the temperature may include a process for measuring the thin-film forming velocity on the target substrate 110, and a process for controlling the TS distance D. In one exemplary embodiment, the depositing source gas generated from the depositing source part 200 is sensed to measure the thin-film forming velocity on the target substrate 110, and then when the thin-film forming velocity is not substantially the same as the predetermined thin-film forming velocity, the TS distance D is changed for the thin-film forming velocity to be substantially equal to the predetermined thin-film forming velocity.

In one exemplary embodiment, the TS distance D is decreased by a control distance ΔD. When the TS distance D is decreased by the control distance ΔD, the thin-film forming velocity on the target substrate 110 may be increased by a second increase thin-film forming velocity ΔV2 corresponding to the control distance ΔD. Thus, the thin-film forming velocity on the target substrate 110 may substantially reach the predetermined thin-film forming velocity.

After the position is controlled, the thin film is deposited. In one exemplary embodiment, the process for depositing the thin film may include a process for depositing the depositing source on the target substrate.

The process for depositing the thin film may include a process for opening the depositing shutter 120 and a process for closing the depositing shutter 120. In one exemplary embodiment, when the depositing shutter 120 is open, the depositing source gas is sequentially deposited on the target substrate 110 by the predetermined thin-film forming velocity. Thus, while the depositing shutter 120 is open, a thickness of the thin-film deposited on the target substrate 110, e.g., a thin-film forming thickness, may be sequentially increased.

When the thin-film forming thickness is increased by an increased thickness ΔFT, the depositing shutter 120 is closed to stop depositing the depositing source on the target substrate 110. In one exemplary embodiment, the thin-film forming velocity is maintained at the predetermined thin-film forming velocity, so that the thin-film forming thickness on the target substrate 110 may be controlled by an opening time of the depositing shutter 120. In one exemplary embodiment, the thin-film forming thickness may be determined by the opening time of the depositing shutter 120.

The process for controlling the temperature according to the present exemplary embodiment has a function that the thin-film forming velocity initially climbs toward the predetermined thin-film forming velocity with a relatively coarse control. However, the process for controlling the position has a function that the thin-film forming velocity finishes its approach to the predetermined thin-film forming velocity with a relatively fine level of control. Accordingly, the thin-film forming velocity initially approaches the predetermined thin-film forming velocity in the process for controlling the temperature, and the thin-film forming velocity reaches the predetermined thin-film forming velocity by accurately controlling the thin-film forming velocity in the process for controlling the position.

In one exemplary embodiment, in the process for controlling the position, the TS distance D may be controlled within a predetermined range. In one exemplary embodiment, the predetermined range may include a range between about 50 mm and about 500 mm.

However, in the process for controlling the position, the TS distance D may be controlled to be out of the predetermined range. In one exemplary embodiment, the TS distance D is controlled to be out of the predetermined range, so that the thin-film forming velocity on the target substrate 110 may need to be controlled. When the TS distance D is controlled to be out of the predetermined range, the temperature may be controlled again. In one exemplary embodiment, in the process for controlling the temperature, the thin-film forming velocity may be changed to reach the predetermined thin-film forming velocity by a large range.

According to the present exemplary embodiment, it takes less time for the thin-film forming velocity to reach the predetermined thin-film forming velocity, in the process for controlling the thin-film forming velocity by controlling the position of the depositing source part 200 rather than that by controlling the temperature of the depositing source part 200. In addition, efficiency in using the depositing source may be enhanced by decreasing the time for the thin-film forming velocity to reach the predetermined thin-film forming velocity. Alternative exemplary embodiments also include configurations wherein the position control process is enacted first and the temperature control process is enacted subsequent to the position control process.

When only the temperature of the depositing source part 200 is controlled, characteristics of the depositing source may be changed by a rapid change of the temperature, so that a malfunction of the thin film deposited on the target substrate 110 may be caused. However, when the position of the depositing source part 200 is controlled in conjunction with the temperature of the depositing source part 200, the characteristics of the depositing source may not be changed, or changed by only a small degree, so that the malfunction of the thin film deposited on the target substrate 110 may be decreased.

Having described the exemplary embodiments of the present invention and its advantages, it is noted that various changes, substitutions and alterations can be made herein without departing from the spirit and scope of the invention as defined by appended claims.

What is claimed is:

1. A method for controlling thin-film forming velocity, the method comprising:
measuring the thin-film forming velocity on a target substrate by sensing a depositing source gas generated from a depositing source part; and
controlling a distance between the depositing source part and the target substrate, so that the thin-film forming velocity substantially equals a predetermined thin-film forming velocity.

2. The method of claim 1, further comprising controlling a quantity of the depositing source gas generated from the depositing source part.

3. The method of claim 2, wherein the controlling a quantity of the depositing source gas includes controlling a temperature of the depositing source part.

4. The method of claim 3, wherein the controlling a quantity of the depositing source gas further includes:
sensing a temperature of the depositing source part; and
controlling the temperature of the depositing source part to substantially equal a predetermined temperature.

5. The method of claim 4, wherein the controlling the distance between the depositing source part and the target substrate is performed after the temperature of the depositing source part substantially reaches the predetermined temperature.

6. The method of claim 5, wherein the distance between the depositing source part and the target substrate is controlled within a predetermined distance range.

7. A method for manufacturing a thin film, the method comprising:
measuring a thin-film forming velocity on a target substrate by sensing a depositing source gas generated from a depositing source part;
controlling a distance between the depositing source part and the target substrate, so that the thin-film forming velocity substantially equals a predetermined thin-film forming velocity; and
depositing a depositing source from the depositing source part on the target substrate with the predetermined thin-film forming velocity.

8. The method of claim 7, further comprising controlling a quantity of the depositing source gas generated from the depositing source part.

9. The method of claim 8, wherein the controlling a quantity of the depositing source gas is performed by controlling a temperature of the depositing source part.

10. The method of claim 7, wherein the depositing a depositing source from the depositing source part on the target substrate further comprises opening a depositing shutter to expose the target substrate when the thin-film forming velocity substantially reaches the predetermined thin-film forming velocity.

11. A system for manufacturing a thin film, the system comprising:
a depositing chamber in which a target substrate is disposed;
a depositing source part, which generates a depositing source gas, disposed in the depositing chamber;
a thin-film forming velocity sensor, which measures a thin-film forming velocity on the target substrate by sensing the depositing source gas; and
a distance control part which controls a distance between the depositing source part and the target substrate so that the thin-film forming velocity substantially equals a predetermined thin-film forming velocity.

12. The system of claim 11, wherein the distance control part comprises:
a thin-film forming velocity controller which outputs a thin-film forming velocity control signal in response to the thin-film forming velocity measured by the thin-film forming velocity sensor;
a position controller which outputs a position variable control signal to control the distance between the depositing source part and the target substrate in response to the thin-film forming velocity control signal; and
a position variable unit which changes the distance between the depositing source part and the target substrate by moving the depositing source part in response to the position variable control signal.

13. The system of claim 11, further comprising a gas generating control part which controls a quantity of the depositing source gas generated from the depositing source part.

14. The system of claim 13, wherein the gas generating control part comprises a temperature control part which controls a temperature of the depositing source part.

15. The system of claim 14, wherein the temperature control part comprises:
a temperature sensor attached to the depositing source part;
a temperature controller which outputs a temperature control signal in response to a temperature sensing signal sent from the temperature sensor; and
a temperature variable unit which changes the temperature in response to the temperature control signal.

16. The system of claim 15, wherein the depositing source part comprises:
an inner container which receives the depositing source; and
a container heater which surrounds the inner container, and which is controlled by the temperature variable unit,
wherein the temperature sensor is attached to the inner container and the temperature sensing signal corresponds to a temperature of the inner container.

17. The system of claim 16, wherein the depositing source part further comprises an external container which receives the container heater and the inner container and which insulates the container heater from an outside.

18. The system of claim 13, further comprising a main controller, which individually controls the distance control part and the gas generating control part, and is electrically connected to the distance control part and the gas generating control part, respectively.

19. The system of claim 11, further comprising a depositing shutter disposed corresponding to the target substrate in the depositing chamber.

20. The system of claim 11, wherein the distance control part stores information on a relationship between the distance between the depositing source part and the target substrate and the thin-film forming velocity.
